(19) United States
(12) Patent Application Publication
(10) Pub. No.: US 2023/0056480 A1
(43) Pub. Date: Feb. 23, 2023

(54) Electroluminescent Display Device

(71) Applicant: LG Display Co., Ltd., Seoul (KR)

(72) Inventors: Suk Yang, Paju-si (KR); HeeSuk Pang, Paju-si (KR); JooHwan Shin, Goyang-si (KR)

(21) Appl. No.: 17/886,894

(22) Filed: Aug. 12, 2022

(30) Foreign Application Priority Data
Aug. 18, 2021 (KR) 10-2021-0108898

(51) Int. Cl. H01L 27/32; H01L 51/56; H01L 51/52

(52) U.S. Cl. CPC H01L 27/3246; H01L 51/56; H01L 51/5225; H01L 51/5253; H01L 2227/323

(57) ABSTRACT

An electroluminescent display device comprises a display panel including an active area and a non-active area; a planarization layer extending to the non-active area of the display panel; a bank on the planarization layer that extends to the non-active area and includes a trench that exposes the planarization layer of the non-active area; an organic layer on the bank and separated by the trench; a cathode on a first organic layer in the inner direction area of the trench; and an adhesive layer and an encapsulation substrate over the cathode, wherein the adhesive layer may be in contact with a second organic layer in the outer direction area of the trench, and reliability can be improved and a bezel width can be reduced.

### CROSS-REFERENCE TO RELATED APPLICATION

This application claims the benefit of and priority to Republic of Korea Patent Application No. 10-2021-0108898 filed on Aug. 18, 2021, which is incorporated by reference in its entirety.

### BACKGROUND

### Technical Field

The present disclosure relates to an electroluminescent display device, and more particularly, to an electroluminescent display device having a narrow bezel.

### Discussion of the Related Art

Recently, as our society advances toward an information-oriented society, the field of display devices for visually expressing an electrical information signal has rapidly advanced. Various display devices having excellent performance in terms of thinness, lightness, and low power consumption, are being developed correspondingly.

Representative display devices include a liquid crystal display device (LCD), an electro-wetting display device (EWD), an organic light emitting display device (OLED), and the like.

Among these various display devices, an electroluminescent display device including an organic light emitting display device is a self-light emitting display device, and can be manufactured to be light and thin since it does not require a separate light source, unlike a liquid crystal display device having a separate light source. In addition, the electroluminescent display device has advantages in terms of power consumption due to a low voltage driving, and is excellent in terms of a color implementation, a response speed, a viewing angle, and a contrast ratio (CR). Therefore, electroluminescent display devices are expected to be utilized in various fields.

The electroluminescent display device is constructed by disposing a light emitting layer using an organic material between two electrodes that are referred to as an anode and a cathode. Then, when holes from the anode are injected into the light emitting layer and electrons from the cathode are injected into the light emitting layer, the injected electrons and holes recombine with each other to form excitons in the light emitting layer and emit light.

### SUMMARY

In current electroluminescent display devices, a minimum bezel distance is required to secure reliability such as moisture permeation prevention or the like, which may be referred to as a reliable bezel. The reliable bezel may be defined as being from an end of an upper substrate (an encapsulation substrate) to an end of a cathode.

Meanwhile, in response to demand for slimming of a display device, demand for slimming of a non-active area of the display device except for an active area in which an image is displayed is also increasing. However, there is a limit in securing a reliable bezel as a cathode needs to be formed to cover an organic layer in order to prevent or at least reduce defects in mass production due to exposure of the organic layer. That is, when the organic layer and the cathode are formed by deposition, a shadow area of a certain length is generated depending on a gap between a deposition mask and a substrate and a deposition method, thereby limiting a reduction of a bezel. In addition, a position and length of the shadow area are non-uniform due to process deviation, and non-uniform quality is caused due to a difference in reliable bezel for each product.

Accordingly, an aspect of the present disclosure is to provide an electroluminescent display device capable of reducing a bezel width by increasing a reliable bezel through blocking a moisture permeation path at a side surface of the display device and retreating an end of a cathode to an active area.

Another aspect of the present disclosure is to provide an electroluminescent display device capable of having improved reliability.

Still another aspect of the present disclosure is to provide an electroluminescent display device capable of smoothly performing cathode delamination.

Objects of the present disclosure are not limited to the above-mentioned objects, and other objects, which are not mentioned above, can be clearly understood by those skilled in the art from the following descriptions.

An electroluminescent display device according to an exemplary embodiment of the present disclosure includes a display panel divided into an active area and a non-active area, a planarization layer extending to the non-active area of the display panel, a bank disposed on the planarization layer to extend to the non-active area and including a trench exposing the planarization layer of the non-active area, an organic layer disposed on the bank and separated by the trench, a cathode disposed on a first organic layer in an inner direction area of the trench and an adhesive layer and an encapsulation substrate disposed over the cathode, wherein the adhesive layer may be in contact with a second organic layer in an outer direction area of the trench.

An electroluminescent display device according to another exemplary embodiment of the present disclosure includes a substrate divided into an active area and a non-active area, a planarization layer disposed on the substrate, a bank disposed on the planarization layer and including a trench formed in the non-active area to expose the planarization layer of the non-active area, a first organic layer and a second organic layer disposed on the bank and separated by the trench, a cathode and a capping layer disposed on the first organic layer and an adhesive layer and an encapsulation substrate disposed on the capping layer, wherein the cathode and the capping layer may not be disposed on the second organic layer and in the trench.

Other detailed matters of the exemplary embodiments are included in the detailed description and the drawings.

According to the present disclosure, a reliable bezel can be increased by forming a trench in a bank of a non-active area, removing a cathode in the outer direction area of the trench to thereby block a moisture permeation path at a side surface of a display device and retreating an end of the cathode to an active area. Accordingly, a bezel width can be reduced.

According to the present disclosure, reliability can be improved by adding an inorganic layer to a side surface of the trench adjacent to the active area.

According to the present disclosure, by adding a step alleviation layer formed of a color filter within the planarization layer in the outer direction area of the trench, cathode delamination can be smoothly performed to improve process properties.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of an electroluminescent display device according to a first exemplary embodiment of the present disclosure;

FIG. 2 is a cross-sectional view of a sub-pixel of the electroluminescence display device according to the first exemplary embodiment of the present disclosure;

FIG. 3 is a cross-sectional view taken along line I-I′ of FIG. 1 according to the first exemplary embodiment of the present disclosure;

FIG. 4 is a partial cross-sectional view of an electroluminescent display device according to a comparative example;

FIG. 5A is a photograph showing a result after cathode delamination according to the comparative example;

FIG. 5B is a photograph showing a result after cathode delamination according to an exemplary embodiment of the present disclosure;

FIG. 6 is a graph showing, as an example, transmittances according to wavelengths of a bank and a planarization layer;

FIG. 7 is a plan view of an electroluminescent display device according to a second exemplary embodiment of the present disclosure;

FIG. 8 is a plan view of an electroluminescent display device according to a third exemplary embodiment of the present disclosure;

FIG. 9 is a cross-sectional view of an electroluminescent display device according to a fourth exemplary embodiment of the present disclosure;

FIG. 10 is a cross-sectional view of an electroluminescent display device according to a fifth exemplary embodiment of the present disclosure;

FIGS. 11A to 11E are cross-sectional views sequentially illustrating parts of a manufacturing process of the electroluminescent display device according to the fifth exemplary embodiment of the present disclosure of FIG. 10.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

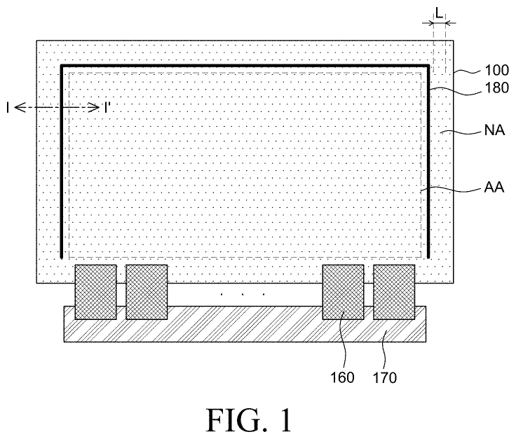

FIG. 1 is a plan view of an electroluminescent display device according to a first exemplary embodiment of the present disclosure.

Referring to FIG. 1, the electroluminescent display device according to the first exemplary embodiment of the present disclosure may include a display panel 100, flexible films 160, and a printed circuit board 170.

The display panel 100 is a panel for displaying an image to a user.

In the display panel 100, display elements for displaying an image, a driving element for driving the display elements, and lines for transmitting various signals to the display elements and the driving element may be disposed. The display element may be defined differently depending on a type of the display panel 100. For example, when the display panel 100 is an organic light emitting display panel, the display element is an organic light emitting element including an anode, an organic light emitting layer, and a cathode.

Hereinafter, it is described assuming that the display panel 100 is an organic light emitting display panel, but the display panel 100 is not limited to the organic light emitting display panel.

The display panel 100 may include an active area AA and a non-active area NA.

The active area AA is an area in which an image is displayed on the display panel 100 according to one embodiment.

A plurality of sub-pixels constituting a plurality of pixels and a circuit for driving the plurality of sub-pixels may be disposed in the active area AA. The plurality of sub-pixels are minimum units constituting the active area AA, and the display element may be disposed in each of the plurality of sub-pixels, and the plurality of sub-pixels may constitute the pixel. For example, an organic light emitting element including an anode, an organic light emitting layer, and a cathode may be disposed in each of the plurality of sub-pixels, but is not limited thereto. In addition, the circuit for driving the plurality of sub-pixels may include a driving element, lines and the like. For example, the circuit may be formed of a thin film transistor, a storage capacitor, a gate line, a data line, and the like, but is not limited thereto.

The non-active area NA is an area in which an image is not displayed according to one embodiment.

FIG. 1 illustrates that the non-active area NA surrounds the active area AA having a quadrangular shape, but shapes and arrangements of the active area AA and the non-active area NA are not limited to the example illustrated in FIG. 1.

In other words, shapes of the active area AA and the non-active area NA may be suitable for a design of an electronic device on which the electroluminescent display device is mounted. For example, other exemplary shapes of the active area AA may be a pentagon, a hexagon, a circle, an oval, and the like.

Various lines and circuits for driving organic light emitting elements of the active area AA may be disposed in the non-active area NA. For example, in the non-active area NA, link lines for transmitting signals to the plurality of sub-pixels and circuits of the active area AA or driver integrated circuits (ICs) such as a gate driver IC and a data driver IC may be disposed, but are not limited thereto.

Meanwhile, left and right sides of FIG. 1 may be defined as a gate pad portion on which the gate driver IC is disposed, and a lower side of FIG. 1 may be defined as a data pad portion to which the flexible films 160 are connected, but the present disclosure is not limited thereto.

The electroluminescent display device may include various additional elements for generating various signals or driving pixels in the active area AA. The additional elements for driving the pixels may include an inverter circuit, a multiplexer, an electro-static discharge (ESD) circuit, and the like. The electroluminescent display device may also include additional elements associated with functions other than driving pixels. For example, the electroluminescent display device may include additional elements that provide a touch sensing function, a user authentication function (e.g., fingerprint recognition), a multi-level pressure sensing function, a tactile feedback function, and the like. Such additional elements may be located in the non-active area NA and/or in an external circuit connected to a connection interface.

The flexible films 160 are films in which various components are disposed on a flexible base film. Specifically, the flexible films 160 are films for supplying signals to the plurality of sub-pixels and circuits of the active area AA, and may be electrically connected to the display panel 100. The flexible films 160 may be disposed at one end of the non-active area NA of the display panel 100 and supply a power voltage, a data voltage and the like to the plurality of sub-pixels and circuits of the active area AA. Meanwhile, the number of flexible films 160 may be variously changed according to design, but is not limited thereto.

A driver IC such as a data driver IC may be disposed on the flexible films 160. The driver IC is a component that processes a data signal for displaying an image and a driving signal for processing it. The driver IC may be disposed in a manner such as a chip-on-glass (COG), chip-on-film (COF), or tape carrier package (TCP) according to a mounting method.

The printed circuit board 170 may be disposed at one end of the flexible films 160 and connected to the flexible films 160. The printed circuit board 170 is a component that supplies signals to the driver IC. The printed circuit board 170 may supply various signals such as a driving signal and a data signal to the driver IC. For example, a data driver generating data signals may be mounted on the printed circuit board 170, and the generated data signals may be supplied to the plurality of sub-pixels and circuits of the display panel 100 through the flexible films 160. The number of printed circuit boards 170 may be variously changed according to design, but is not limited thereto.

Meanwhile, the electroluminescent display device requires a minimum bezel distance (e.g., a predetermined distance) to secure reliability such as moisture permeation prevention or the like, and demand for slimming of the non-active area NA except for the active area AA where an image is displayed, is also increasing in accordance with demand for slimming of display devices. However, there is a limit in securing a reliable bezel L as the cathode needs to be formed to cover a side surface of an organic layer in order to prevent or at least reduce a defect in mass production due to exposure of the organic layer. In this case, the reliable bezel L may be defined as being from an end of an upper substrate (encapsulation substrate) to an end of the cathode.

Accordingly, in the first exemplary embodiment of the present disclosure, it is characterized in that a trench 180 is formed in a bank of the non-active area NA, in particular, a shadow area, and a capping layer, the cathode, and the organic layer on the trench 180 are removed to thereby block moisture permeation to a side surface of the display device. In addition, in the first exemplary embodiment of the present disclosure, it is characterized in that moisture absorption of the adhesive layer is facilitated by removing the capping layer and the cathode in the outer direction area of the trench 180. In addition, the end of the cathode may be retreated in a direction of the active area AA, so that the reliable bezel L may increase, thereby reducing a bezel width.

For reference, the shadow area is a margin area generated by a gap between a mask and the substrate when the cathode and the organic layer are deposited, and may be included in the non-active area NA.

The trench 180 according to the first exemplary embodiment of the present disclosure may be formed, for example, in three surfaces of the non-active area NA except for a lower side of the display panel 100 to which the flexible films 160 are connected, that is, a data pad portion, but the present disclosure is not limited thereto. That is, the trench 180 may not be formed in the data pad portion because it is difficult to form the trench 180 in the data pad portion due to a wide line area of the data pad portion, but the present disclosure is not limited thereto.

In this manner, the trench 180 is formed, for example, by removing a portion of the bank in the shadow area outside the active area AA. Also, the capping layer, the cathode, and the organic layer on the trench 180 may be removed by irradiating a laser of a predetermined wavelength, thereby blocking a moisture permeation path to the side surface of the display device. In addition, by removing (or delaminating) the capping layer and the cathode in the outer direction area of the trench 180 through a stamping method or the like, moisture absorption into the adhesive layer is facilitated, and accordingly, the end of the cathode is retreated to the active area AA, so that the reliable bezel L can be increased and a bezel width can be reduced. For example, when the trench 180 is formed in three surfaces of the non-active area NA except for the data pad portion, laser irradiation and cathode removal may also be performed on the three surfaces of the non-active area NA except for the data pad portion. However, the present disclosure is not limited thereto.

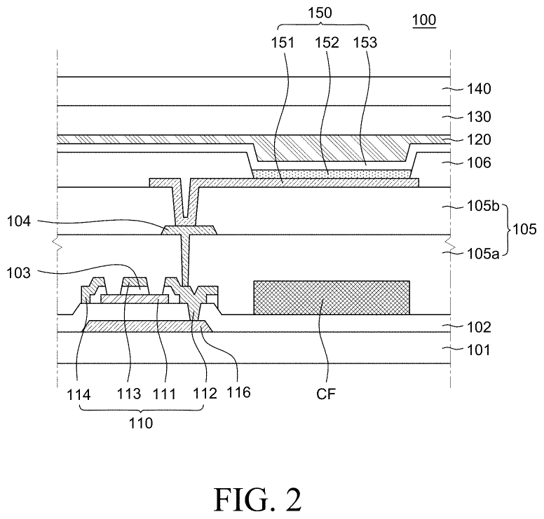

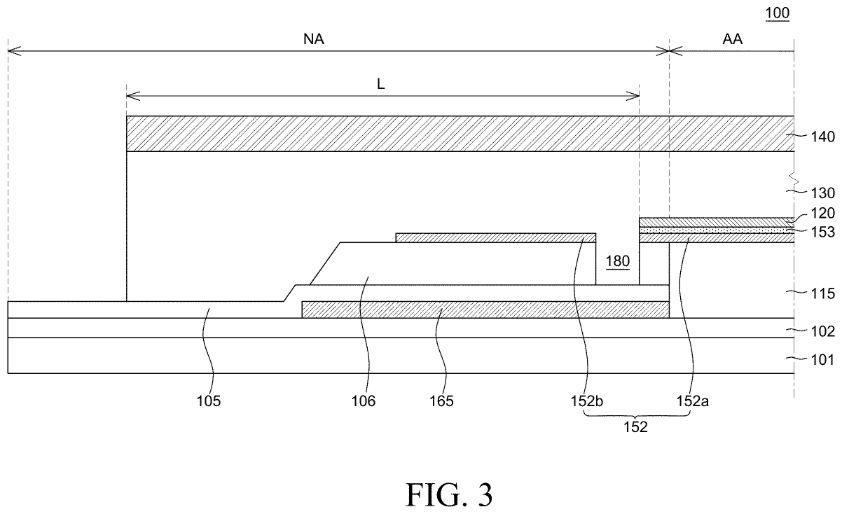

Various components constituting the electroluminescent display device according to the first exemplary embodiment of the present disclosure, including the trench 180, will be described in detail with reference to FIGS. 2 and 3.

FIG. 2 is a cross-sectional view of a sub-pixel of the electroluminescence display device according to the first exemplary embodiment of the present disclosure.

FIG. 3 is a cross-sectional view taken along line I-I′ of FIG. 1 according to the first exemplary embodiment of the present disclosure.

FIG. 3 shows, for example, a cross-section of a portion, of a right side of the display panel 100 in which the trench 180 is formed, that is, the gate pad portion. In FIG. 3, a pixel unit 115 in the active area AA and a circuit unit 165 in the non-active area NA are simply illustrated for convenience of description. The pixel unit 115 may include various components under an organic layer 152. In addition, the circuit unit 165 may include various components including a gate-in-panel (GIP) unit, but the present disclosure is not limited thereto.

Referring to FIGS. 2 and 3, in the electroluminescent display device according to the first exemplary embodiment of the present disclosure, a driving element 110 may be disposed on a substrate 101.

In addition, a planarization layer 105 may be disposed on the driving element 110.

In addition, an organic light emitting element 150 that is electrically connected to the driving element 110 is disposed on the planarization layer 105, and a capping layer 120 may be disposed on the organic light emitting element 150 to thereby minimize or at least reduce penetration of oxygen and moisture to the organic light emitting element 150.

An adhesive layer 130 and an encapsulation substrate 140 may be sequentially disposed on the capping layer 120. However, the present disclosure is not limited to such a stacked structure.

The substrate 101 may be a glass or plastic substrate. In the case of the plastic substrate, a polyimide-based or polycarbonate-based material may be used to have flexibility. In particular, polyimide is widely used for a plastic substrate because it can be applied to high-temperature processes and can be coated.

A buffer layer 102 may be disposed on the substrate 101.

The buffer layer 102, a functional layer for protecting various electrodes and lines from impurities such as alkali ions leaking from the substrate 101 or underlayers thereof, may have a multilayer structure formed of a first buffer layer and a second buffer layer, but the present disclosure is not limited thereto. The buffer layer 102 may be formed of silicon oxide (SiOx), silicon nitride (SiNx), or a multilayer thereof.

The buffer layer 102 may delay diffusion of moisture and/or oxygen permeating into the substrate 101. Also, the buffer layer 102 may include a multi-buffer and/or an active buffer. The active buffer may protect an active layer 111 composed of a semiconductor of the driving element 110 and block various types of defects introduced from the substrate 101. The active buffer may be formed of, for example, amorphous silicon (a-Si) or the like.

A light blocking layer 116 may be disposed between the substrate 101 and the buffer layer 102.

The light blocking layer 116 may be disposed at a position where the active layer 111 is to be formed on the substrate 101. In particular, a size of the light blocking layer 116 is slightly larger than the active layer 111 to completely cover the active layer 111 in one embodiment. However, the present disclosure is not limited thereto.

The buffer layer 102 may be disposed on an entire surface of the substrate 101 on which the light blocking layer 116 is formed.

The driving element 110 may be disposed on the buffer layer 102.

The driving element 110 may have a form in which the active layer 111, an interlayer insulating layer 103, a gate electrode 113, a source electrode 114, and a drain electrode 112 are sequentially disposed, and may be electrically connected to the organic light emitting element 150 through a connection electrode 104 to thereby transmit a current or a signal to the organic light emitting element 150.

The active layer 111 may be positioned on the buffer layer 102. The active layer 111 may be formed of polysilicon (p-Si), and in this case, a predetermined area thereof may be doped with impurities. In addition, the active layer 111 may be formed of amorphous silicon (a-Si) or various organic semiconductor materials such as pentacene and the like. Furthermore, the active layer 111 may be formed of an oxide.

The interlayer insulating layer 103 may be positioned on the active layer 111.

The interlayer insulating layer 103 may be formed of an insulating inorganic material such as silicon oxide (SiOx) or silicon nitride (SiNx), and besides, may also be formed of an insulating organic material or the like.

The gate electrode 113 may be positioned on the interlayer insulating layer 103. The gate electrode 113 may be formed of various conductive materials, for example, magnesium (Mg), aluminum (Al), nickel (Ni), chromium (Cr), molybdenum (Mo), tungsten (W), gold (Au), or alloys of them.

The source electrode 114 and the drain electrode 112 may be formed on the interlayer insulating layer 103 in a single layer or multilayer structure as an electrode material. The source electrode 114 and the drain electrode 112 may be formed of various conductive materials, for example, magnesium (Mg), aluminum (Al), nickel (Ni), chromium (Cr), molybdenum (Mo), tungsten (W), gold (Au) or an alloy thereof.

If necessary, a passivation layer formed of an inorganic insulating material may be additionally formed to cover the gate electrode 113, and the source electrode 114 and the drain electrode 112.

The planarization layer 105 may be disposed on the driving element 110 configured as described above.

In this case, in a bottom emission method, a color filter layer CF formed of a color filter may be formed on the buffer layer 102 under the organic light emitting element 150, but the present disclosure is not limited thereto. In this case, the planarization layer 105 may be disposed to cover the color filter layer CF.

The planarization layer 105 may have a multilayer structure composed of at least two layers, and for example, may include a first planarization layer 105a and a second planarization layer 105b. In this case, the first planarization layer 105a may be disposed to cover the driving element 110, and may be disposed such that a portion of the drain electrode 112 of the driving element 110 is exposed.

The planarization layer 105 may extend to the non-active area NA.

The planarization layer 105 may have a thickness of about 2 μm, but is not limited thereto.

The planarization layer 105 may include an overcoat layer, but is not limited thereto.

The connection electrode 104 for electrically connecting the driving element 110 and the organic light emitting element 150 with each other may be disposed on the first planarization layer 105a. In addition, although not shown in FIG. 2, various metallic layers serving as lines/electrodes such as data lines and signal lines may be disposed on the first planarization layer 105a.

In addition, the second planarization layer 105b may be disposed on the first planarization layer 105a and the connection electrode 104. The planarization layer 105 according to the first exemplary embodiment of the present disclosure is formed of two layers due to an increase in the number of various signal lines as the electroluminescent display device has a higher resolution. Therefore, an additional layer is prepared because it is difficult to arrange all lines on one layer while securing a minimum distance between the lines. The addition of such an additional layer (the second planarization layer 105b) provides a place for line arrangement, so that line/electrode arrangement design may be further facilitated. In addition, if a dielectric material is used as the planarization layer 105 composed of multiple layers, the planarization layer 105 may be utilized for a purpose of forming capacitance between metallic layers. However, the present disclosure is not limited thereto.

The second planarization layer 105b may be formed such that a portion of the connection electrode 104 is exposed, and the drain electrode 112 of the driving element 110 and the anode of the organic light emitting element 150 may be electrically connected to each other by the connection electrode 104.

The organic light emitting element 150 may be configured by sequentially disposing an anode 151, one or more organic layers 152, and a cathode 153. That is, the organic light emitting element 150 may include the anode 151 that is formed on the planarization layer 105, the organic layer 152 that is formed on the anode 151, and the cathode 153 that is formed on the organic layer 152.

The electroluminescent display device may be implemented in a top emission method or a bottom emission method. In the case of the top emission method, a reflective layer formed of an opaque conductive material with high reflectivity, for example, silver (Ag), aluminum (Al), gold (Au), molybdenum (Mo), tungsten (W), chromium (Cr), or an alloy thereof, may be added under the anode 151 so that light emitted from the organic layer 152 is reflected by the anode 151 and is directed upwardly, that is, in a direction of the cathode 153 disposed thereover. Conversely, in the case of the bottom emission method, the anode 151 may be formed of only a transparent conductive material such as indium tin oxide (ITO), indium zinc oxide (IZO), or indium gallium zinc oxide (IGZO). Hereinafter, it is described assuming that the electroluminescent display device of the present disclosure is in the bottom emission method.

A bank 106 may be formed in an area other than a light emitting area on the planarization layer 105. That is, the bank 106 has a bank hole that exposes the anode 151 corresponding to the light emitting area. The bank 106 may be formed of an inorganic insulating material such as silicon nitride (SiNx) or silicon oxide (SiOx), or an organic insulating material such as BCB, acrylic resin, or imide resin.

The bank 106 may extend to the non-active area NA.

The trench 180 may be formed (patterned) in the bank 106 of the non-active area NA to expose the planarization layer 105.

The bank 106 of the non-active area NA may be separated by the trench 180.

The bank 106 may have a thickness of about 1 μm, but is not limited thereto.

The organic layer 152 may be disposed on the anode 151 that is exposed by the bank 106. The organic layer 152 may include the light emitting layer, an electron injection layer, an electron transport layer, a hole transport layer, a hole injection layer, and the like.

The organic layer 152 may extend to the non-active area NA.

In the non-active area NA, the organic layer 152 may be separated by the trench 180 via laser irradiation. That is, the organic layer 152 may be separated into a first organic layer 152a in an inner direction area of the trench 180 and a second organic layer 152b in an outer direction area of the trench 180. Hereinafter, the inner direction area of the trench indicates an area placed in a direction to the active area AA from the trench, and the outer direction area of the trench indicates an area placed in a direction to the end of the substrate from the trench.

In the non-active area NA, the second organic layer 152b may be disposed to be spaced apart from an end of the bank 106 by a predetermined distance.

The cathode 153 may be disposed on the organic layer 152. That is, the cathode 153 may be disposed on the first organic layer 152a.

The cathode 153 may partially extend to the non-active area NA. For example, the first organic layer 152a may be disposed to extend over the bank 106 in the inner direction area of the trench 180, and the cathode 153 may be disposed over the first organic layer 152a.

In the case of the top emission method, the cathode 153 may include a transparent conductive material. For example, the cathode 153 may be formed of indium tin oxide (ITO), indium zinc oxide (IZO), indium gallium zinc oxide (IGZO), or the like. In the case of the bottom emission method, the cathode 153 may include any one of metallic materials such as gold (Au), silver (Ag), aluminum (Al), molybdenum (Mo), magnesium (Mg), palladium (Pd), copper (Cu) or the like, or groups consisting of alloys thereof. Alternatively, the cathode 153 may be configured by stacking a layer formed of a transparent conductive material such as indium tin oxide (ITO), indium zinc oxide (IZO) or indium gallium zinc oxide (IGZO), and a layer formed of a metallic material such as gold (Au), silver (Ag), aluminum (Al), molybdenum (Mo), magnesium (Mg), palladium (Pd), copper (Cu) or the like, or alloys thereof, but is not limited thereto.

In order to reduce diffused reflection of external light, the capping layer 120 formed of a material having a high refractive index and light absorption may be disposed on the organic light emitting element 150.

The capping layer 120 may be an organic layer formed of an organic material, and may be omitted if necessary.

The capping layer 120 may partially extend to the non-active area NA. For example, the first organic layer 152a and the cathode 153 may be disposed to extend over the bank 106 inside the trench 180, and the capping layer 120 may be disposed on the cathode 153. As described above, in the non-active area NA, the capping layer 120 may be disposed on the cathode 153 in the inner direction area of the trench 180. For example, the capping layer 120 together with the cathode 153 may be disposed to be spaced apart from an inner end of the second organic layer 152b by a predetermined distance, but is not limited thereto.

In FIG. 3, a case where ends of the first organic layer 152a, the cathode 153, and the capping layer 120 coincide with one another is illustrated as an example, but the present disclosure is not limited thereto. In particular, in FIG. 3, a case where ends of the first organic layer 152a, the cathode 153, the capping layer 120 and the bank 106 in the inner direction area of the trench 180 coincide with one another is illustrated as an example, but the present disclosure is limited thereto. Also, in FIG. 3, a case where inner ends of the bank 106 in the outer direction area of the trench 180 and the second organic layer 152b coincide with one another is illustrated as an example, but the present disclosure is not limited thereto.

The first exemplary embodiment of the present disclosure is characterized in that the capping layer 120 and the cathode 153 are not disposed on the trench 180 and the second organic layer 152b in the non-active area NA. That is, the capping layer 120, the cathode 153, and the organic layer 152 on the trench 180 are removed through laser irradiation, and the capping layer 120 and the cathode 153 on the second organic layer 152b in the outer direction area of the trench 180 may be removed (or delaminated) through a stamping method or the like. Accordingly, by retreating an end of the cathode 153 to the active area AA, the reliable bezel L is increased, so that a bezel width may be reduced.

The adhesive layer 130 and the encapsulation substrate 140 may be disposed on the capping layer 120.

The adhesive layer 130 and the encapsulation substrate 140 may extend to the non-active area NA to partially cover the planarization layer 105. The adhesive layer 130 and the encapsulation substrate 140 may expose other portions of the planarization layer 105, but the present disclosure is not limited thereto.

Also, the adhesive layer 130 may extend to the non-active area NA so as to cover a portion of the planarization layer 105 and the bank 106 including an inner portion of the trench 180.

Also, the adhesive layer 130 may be disposed to cover the capping layer 120 and the pixel unit 115. The adhesive layer 130 together with the capping layer 120 and the encapsulation substrate 140 may protect the organic light emitting element 150 of the pixel unit 115 from external moisture, oxygen, impacts, and the like. The adhesive layer 130 may further include getter in one embodiment. The getter may be particles having hygroscopicity, and may absorb moisture and oxygen from the outside, thereby reducing penetration of moisture and oxygen into the pixel unit 115. In particular, in the present disclosure, as the capping layer 120 and the cathode 153 in the outer direction area of the trench 180 are removed, moisture absorption of the adhesive layer 130 may be facilitated.

The encapsulation substrate 140 may be disposed on the adhesive layer 130. The encapsulation substrate 140 may protect the organic light emitting element 150 of the pixel unit 115 together with the adhesive layer 130. The encapsulation substrate 140 may protect the organic light emitting element 150 from external moisture, oxygen, impacts, and the like.

Meanwhile, as described above, the electroluminescent display device requires a minimum bezel distance (e.g., a predetermined distance), that is, the reliable bezel L, in order to secure reliability such as moisture permeation prevention or the like.

The reliable bezel L may be defined as a distance from an end of the encapsulation substrate 140 to the end of the cathode 153.

An area other than the reliable bezel L in the non-active area NA may be referred to as a shadow area and is located outside the active area AA. The shadow area may be defined by a gap between the mask and the substrate 101 when the cathode 153 and the organic layer 152 are deposited.

In the first exemplary embodiment of the present disclosure, it is characterized in that the trench 180 is disposed outside the shadow area, that is, in the reliable bezel L. In addition, it is characterized in that the capping layer 120 and the cathode 153 on the second organic layer 152b are removed in the reliable bezel L.

In FIG. 3, a case in which the trench 180 is configured in one line is exemplified, but the present disclosure is not limited thereto. The trench 180 may be formed as two or more lines, and the present disclosure is not limited to the number of lines of the trench 180.

As described above, in the first exemplary embodiment of the present disclosure, it is characterized in that the capping layer 120 and the cathode 153 are not disposed on the trench 180 and the second organic layer 152b in the non-active area NA. For example, the capping layer 120, the cathode 153, and the organic layer 152 on the trench 180 are removed through laser irradiation, and the capping layer 120 and the cathode 153 on the second organic layer 152b in the outer direction area of the trench 180 may be removed through a stamping method or the like. For example, when the trench 180 is formed in three surfaces of the non-active area NA except for the data pad portion, laser irradiation and removal of the cathode 153 may also be performed on three surfaces of the non-active area NA except for the data pad portion, but the present disclosure is not limited thereto.

The first organic layer 152a and the second organic layer 152b disposed on the banks 106 may be separated by the trench 180.

The inner portion of the trench 180 may be filled with the adhesive layer 130, but is not limited thereto. A material filing the inner portion of the trench 180 may be any material as long as it can prevent or at least reduce moisture permeation. Meanwhile, an inorganic layer formed of an inorganic insulating material may be additionally disposed on the capping layer 120 including a side surface of the trench 180, and the inorganic layer may be formed of silicon oxide (SiOx), silicon nitride (SiNx), or a multilayer thereof. In this case, moisture permeation delay effects may be increased, so that the reliable bezel may be further increased.

In this manner, in the first exemplary embodiment of the present disclosure, the trench 180 is formed in the non-active area NA, the capping layer 120, the cathode 153, and the organic layer 152 on the trench 180 are removed through laser irradiation to thereby block or at least reduce moisture permeation to the side surface of the display device, and the capping layer 120 and the cathode 153 on the second organic layer 152b in the outer direction area of the trench 180 are removed through a stamping method or the like, so that the end of the cathode 153 may be retreated to the active area AA. Accordingly, a bezel width W can be reduced by converting the shadow area into an area of the reliable bezel L, which will be described in detail through a comparative example.

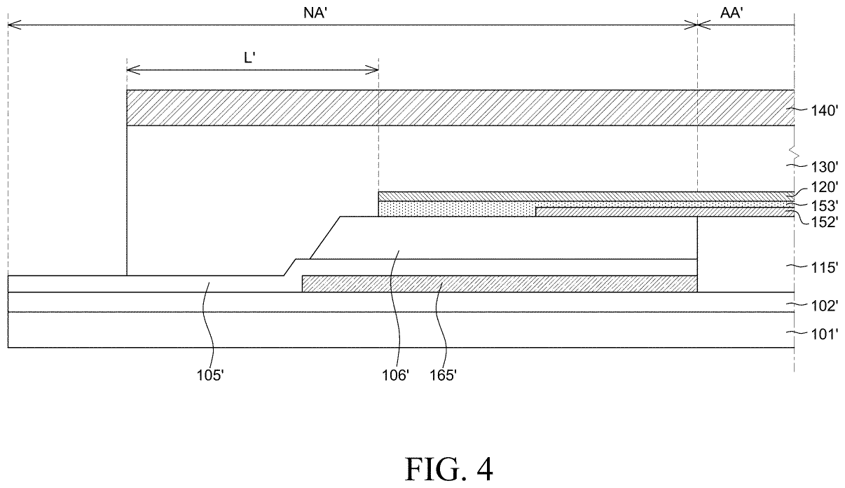

FIG. 4 is a partial cross-sectional view of an electroluminescent display device according to a comparative example.

An electroluminescent display device according to the comparative example of FIG. 4 has no trench and has substantially the same configuration with the exception that the cathode 153 is formed to cover the organic layer 152, compared to the electroluminescent display device according to the first exemplary embodiment of the present disclosure of FIG. 3 described above.

As described above, in FIG. 4, a pixel unit 115′ in an active area AA′ and a circuit unit 165′ in a non-active area NA′ are simply illustrated for convenience of description.

Referring to FIG. 4, in the electroluminescent display device according to the comparative example, a buffer layer 102′ and a driving element may be disposed on a substrate 101′.

In addition, a planarization layer 105′ may be disposed on the driving element.

An organic light emitting element that is electrically connected to the driving element may be disposed on the planarization layer 105′, and a capping layer 120′ may be disposed on the organic light emitting element. The organic light emitting element may be configured by sequentially disposing an anode, an organic layer 152′, and a cathode 153′.

A bank 106′ may be disposed in a remaining area other than an emission area, on the planarization layer 105′.

An adhesive layer 130′ and an encapsulation substrate 140′ may be sequentially disposed on the capping layer 120′.

Meanwhile, in the electroluminescent display device according to the comparative example, it is characterized in that the trench according to the first exemplary embodiment of the present disclosure does not exist, and the cathode 153′ is formed to cover the organic layer 152′ in order to prevent or at least reduce defects in mass production due to exposure of the organic layer 152′. Accordingly, it can be seen that a reliable bezel L′ cannot be sufficiently secured, and as a result, it can be seen that the non-active area NA′ is increased compared to the electroluminescent display device of the first exemplary embodiment of the present disclosure of FIG. 3.

Meanwhile, in the present disclosure, an existing shadow area is converted into a reliable bezel by removing an unnecessary cathode in the shadow area generated by a deposition mask, so that a bezel width can be reduced.

Meanwhile, to remove (or delaminate) the unnecessary cathode in the shadow area, a stamping method using a weak adhesive force between the organic layer and the cathode may be applied.

At this time, when the capping layer, the cathode, and the organic layer are separated by the trench by irradiating a laser before delamination of the cathode, the delamination of the cathode may be performed smoothly, which will be described in detail with reference to the drawings.

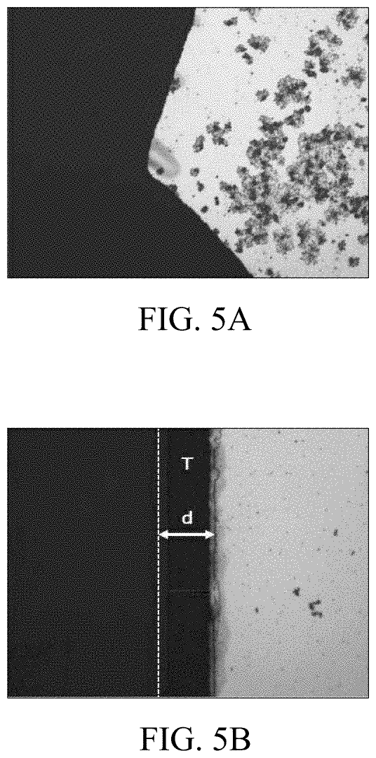

FIG. 5A is a photograph showing a result after cathode delamination according to the comparative example.

FIG. 5B is a photograph showing a result after cathode delamination according to an exemplary embodiment of the present disclosure.

FIGS. 5A and 5B show, for example, a cathode delamination result in a case in which an organic layer, a cathode, and a capping layer are sequentially formed on glass. The cathode delamination may be performed, for example, by bringing a stamp to which an adhesive or adhesive tape is attached into contact with the capping layer in the outer direction area of the trench and applying pressure thereto, but the present disclosure is not limited thereto. For reference, the cathode delamination includes delamination of the capping layer and the organic layer as well as the cathode, but for convenience, it will be referred to as cathode delamination.

FIG. 5A shows a cathode delamination result without laser irradiation, and FIG. 5B shows a cathode delamination result after laser irradiation. In addition, left sides of FIGS. 5A and 5B show portions where the capping layer, the cathode, and the organic layer are delaminated.

In FIG. 5B, T represents a laser irradiation area, and the laser irradiation area T may have a width d of, for example, about 30 μm.

Referring to FIG. 5A, according to the comparative example, it can be seen that when cathode delamination is performed without laser irradiation, the cathode delamination is performed jaggedly at an interface.

Meanwhile, referring to FIG. 5B, according to the exemplary embodiment of the present disclosure, it can be seen that when the capping layer, the cathode, and the organic layer are separated by the trench by irradiating a laser before delamination of the cathode, cathode delamination is performed smoothly along an interface.

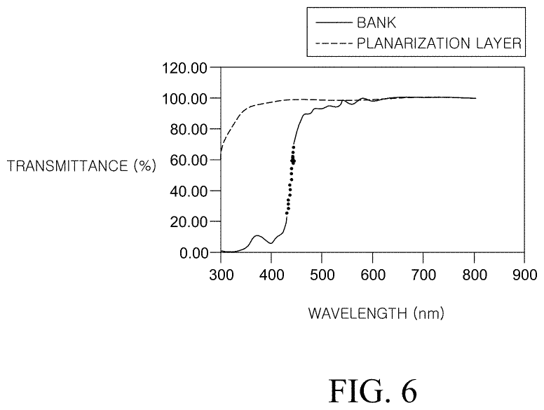

FIG. 6 is a graph showing, as an example, transmittances according to wavelengths of a bank and a planarization layer.

In the case of lower layers of the organic light emitting element, when a transmittance to an irradiated laser is high, they do not participate in reaction. Thus, the bank needs to be removed from an area to which the laser is irradiated, and in the present disclosure, a laser may be irradiated onto the triple layer of capping layer, the organic layer, the cathode on the trench.

That is, referring to FIG. 6, it can be seen that the planarization layer has a transmittance of about 60% at a wavelength of 300 nm, and the transmittance also rapidly increases as the wavelength increases.

Meanwhile, in the case of the bank, it can be seen that the transmittance is 0 to 20%, which is low at a wavelength of 300 nm to 440 nm, and the transmittance rapidly increases at a wavelength of 440 nm or more.

For example, it can be seen that the transmittances of the bank and the planarization layer at a UV laser of 355 nm are 2.8% and 95.0%, respectively.

That is, in the case of the bank, the absorption rate is relatively high at the UV laser of 355 nm, which affects a removal of the triple layer above the bank, so the bank below an area where a laser is irradiated is removed (patterned) in advance to form a trench in the present disclosure.

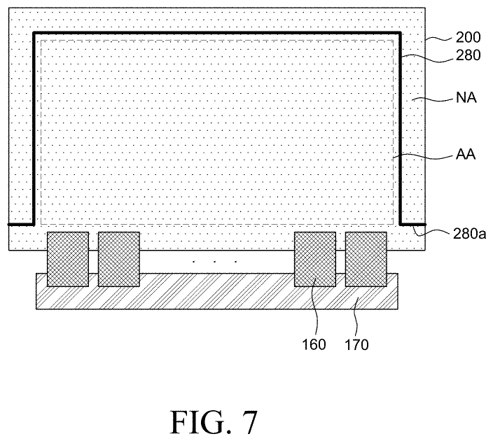

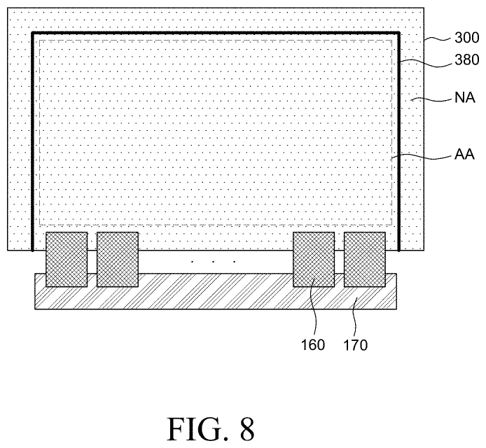

Meanwhile, the trench of the present disclosure may be extended or formed outwardly from the data pad portion or may be extended and formed downwardly, which will be described in detail with reference to FIGS. 7 and 8 below.

FIG. 7 is a plan view of an electroluminescent display device according to a second exemplary embodiment of the present disclosure.

FIG. 8 is a plan view of an electroluminescent display device according to a third exemplary embodiment of the present disclosure.

FIG. 7 exemplifies a case in which a trench 280 is extended and formed outwardly from a data pad portion, and FIG. 8 exemplifies a case in which a trench 380 is extended and formed downward toward a data pad portion.

Since the second exemplary embodiment and the third exemplary embodiment of the present disclosure shown in FIGS. 7 and 8 differ from the electroluminescent display device according to the first exemplary embodiment of the present disclosure of FIG. 1 described above, only in terms of arrangement forms of the trenches 280 and 380, and other configurations thereof are substantially the same, a redundant description will be omitted. The same reference numerals are used for the same components.

Referring to FIGS. 7 and 8, the electroluminescent display device according to the second exemplary embodiment and the third exemplary embodiment of the present disclosure includes display panels 200 and 300, the flexible films 160, and the printed circuit boards 170.

The display panels 200 and 300 may include an active area AA and a non-active area NA.

In the same manner as in the first exemplary embodiment of the present disclosure described above, left and right sides of FIGS. 7 and 8 may be defined as gate pad portions on which gate driver ICs are disposed, and lower sides of FIGS. 7 and 8 may be defined as data pad portions to which the flexible films 160 are connected, but the present disclosure is not limited thereto.

In addition, in the second exemplary embodiment and the third exemplary embodiment of the present disclosure, it is characterized in that the trenches 280 and 380 are formed in banks of the non-active areas NA, particularly, in shadow areas, and capping layers, cathodes and organic layers on the trenches 280 and 380 are removed to thereby block moisture permeation to side surfaces of the display devices. In addition, in the second exemplary embodiment and the third exemplary embodiment of the present disclosure, it is characterized in that the capping layers and the cathodes in the outer direction area of the trenches 280 and 380 are removed to facilitate moisture absorption of the adhesive layer, and ends of the cathodes can be retreated in a direction of the active areas AA. Accordingly, a reliable bezel can be increased and a bezel width can be reduced.

The trenches 280 and 380 according to the second exemplary embodiment and the third exemplary embodiment of the present disclosure may be formed, for example, in three surfaces of the non-active areas NA except for lower sides of the display panels 200 and 300 to which the flexible films 160 are connected, that is, the data pad portions, but the present disclosure is not limited thereto.

In particular, the trench 280 according to the second exemplary embodiment of the present disclosure is characterized by including an extension portion 280a extending outwardly from the data pad portion to an end of a substrate.

In addition, the trench 380 according to the third exemplary embodiment of the present disclosure is characterized in that it extends downward toward the data pad portion to an end of a substrate.

Accordingly, it is possible to partially block side moisture permeation into the data pad portions in which the trenches 280 and 380 are not formed. In addition, as the trenches 280 and 380 are formed up to the ends of the substrates, cathode delamination can be performed more smoothly.

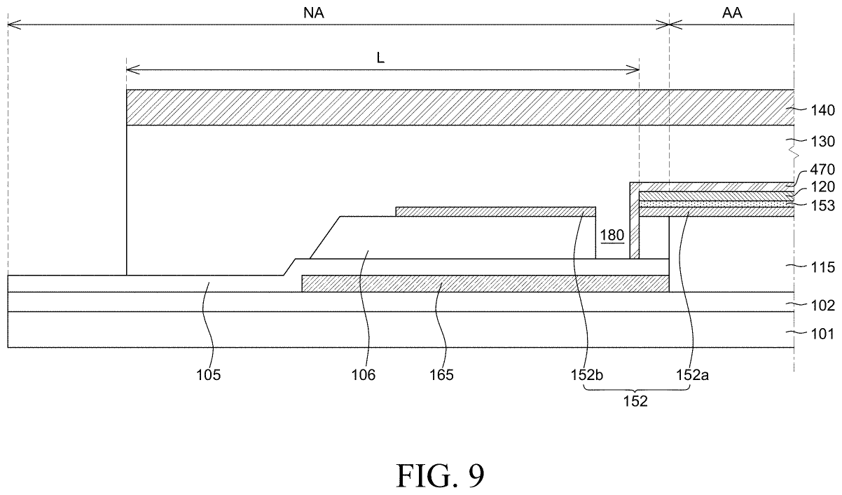

Meanwhile, the inner portion of the trench of the present disclosure may be filled with an adhesive layer, but the present disclosure is not limited thereto, and an inorganic layer may be additionally disposed on the capping layer including one side surface of the trench, which will be described in detail with reference to FIG. 9 below.

FIG. 9 is a cross-sectional view of an electroluminescent display device according to a fourth exemplary embodiment of the present disclosure.

Since the fourth exemplary embodiment of the present disclosure shown in FIG. 9 differs from the electroluminescent display device according to the first exemplary embodiment of the present disclosure of FIG. 3 described above, only in that an inorganic layer 470 formed of an inorganic insulating material is additionally disposed on the capping layer 120 including one side surface of the trench 180, and other components thereof are substantially the same, a redundant description will be omitted. The same reference numerals are used for the same components.

Referring to FIG. 9, in the electroluminescent display device according to the fourth exemplary embodiment of the present disclosure, the buffer layer 102 and a driving element may be disposed on the substrate 101.

In addition, the planarization layer 105 may be disposed on the driving element.

Also, an organic light emitting element that is electrically connected to the driving element may be disposed on the planarization layer 105, and the capping layer 120 may be disposed on the organic light emitting element.

The adhesive layer 130 and the encapsulation substrate 140 may be sequentially disposed on the capping layer 120. However, the present disclosure is not limited to such a stacked structure.

The bank 106 may be disposed in a remaining area other than an emission area, on the planarization layer 105.

As in the first exemplary embodiment of the present disclosure described above, the trench 180 may be formed (patterned) to expose the planarization layer 105 in the bank 106 of the non-active area NA.

The bank 106 of the non-active area NA may be separated by the trench 180.

For example, the trench 180 may be formed in three surfaces of the non-active area NA except for the data pad portion, but is not limited thereto.

In the non-active area NA, the organic layer 152 may be separated by the trench 180 via laser irradiation. That is, the organic layer 152 may be separated into the first organic layer 152a in the inner direction area of the trench 180 and the second organic layer 152b in the outer direction area of the trench 180.

The cathode 153 may be disposed on the organic layer 152. That is, the cathode 153 may be disposed on the first organic layer 152a.

The cathode 153 may partially extend to the non-active area NA. For example, the first organic layer 152a may be disposed to extend over the bank 106 in the inner direction area of the trench 180, and the cathode 153 may be disposed over the first organic layer 152a.

The capping layer 120 may partially extend to the non-active area NA. For example, the first organic layer 152a and the cathode 153 may be disposed to extend over the bank 106 in the inner direction area of the trench 180, and the capping layer 120 may be disposed over the cathode 153. In this manner, in the non-active area NA, the capping layer 120 may be disposed on the cathode 153 in the inner direction area of the trench 180. For example, the capping layer 120 together with the cathode 153 may be disposed to be spaced apart from the inner end of the second organic layer 152b by a predetermined distance, but is not limited thereto.

In the fourth exemplary embodiment of the present disclosure, it is characterized in that the capping layer 120 and the cathode 153 are not disposed on the trench 180 and the second organic layer 152b in the non-active area NA. That is, the capping layer 120, the cathode 153, and the organic layer 152 on the trench 180 are removed through laser irradiation, and the capping layer 120 and the cathode 153 on the second organic layer 152b in the outer direction area of the trench 180 may be removed (or delaminated) through a stamping method or the like. Accordingly, by retreating the end of the cathode 153 to the active area AA, the reliable bezel L is increased to thereby reduce the bezel width. For example, when the trench 180 is formed in three surfaces of the non-active area NA except for the data pad portion, laser irradiation and removal of the cathode 153 are also performed on three surfaces of the non-active area NA except for the data pad portion, but the present disclosure is not limited thereto.

In addition, in the fourth exemplary embodiment of the present disclosure, it is characterized in that the inorganic layer 470 formed of an inorganic insulating material is additionally disposed on the capping layer 120 including one side surface of the trench 180. The inorganic layer may be formed of silicon oxide (SiOx), silicon nitride (SiNx), or a multilayer thereof. In this case, moisture permeation delay effects are increased, so that the reliable bezel L may be further increased, and reliability may also be improved.

FIG. 9 illustrates a case in which the inorganic layer 470 covers side surfaces of the first organic layer 152a, the cathode 153, the capping layer 120, and the bank 106 in the inner direction area of the trench 180, and an upper portion of the capping layer 120, as an example, but the present disclosure is not limited thereto. The inorganic layer 470 according to the fourth exemplary embodiment of the present disclosure may be disposed over an upper portion of the second organic layer 152b and the upper portion of the capping layer 120 including the inner portion of the trench 180. In addition, the inorganic layer 470 according to the fourth exemplary embodiment of the present disclosure may be extended and disposed to cover not only the upper portion of the second organic layer 152b and the upper portion of the capping layer 120 including the inner portion of the trench 180, but also the side surface of the bank 106 in the non-active area NA.

Also, the adhesive layer 130 may be disposed to cover the inorganic layer 470 including the inside of the trench 180.

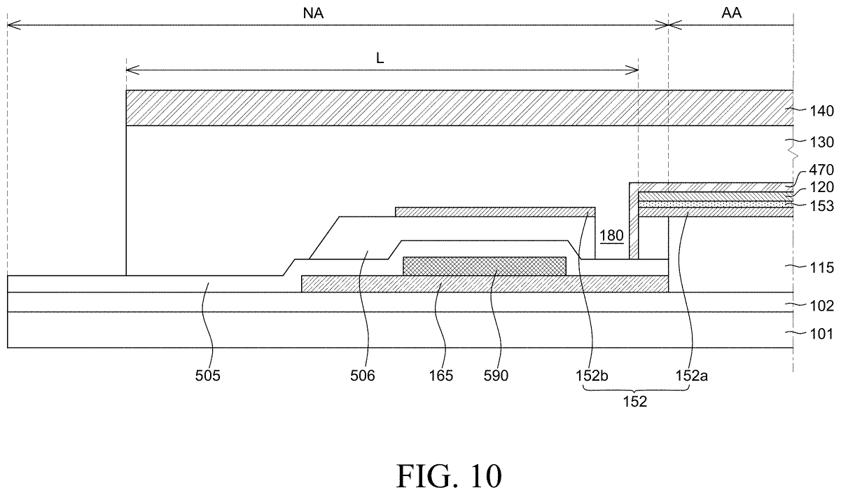

Meanwhile, in the present disclosure, cathode delamination can be smoothly performed by adding a step alleviation layer composed of a color filter within the planarization layer in the outer direction area of the trench, which will be described in detail with reference to FIG. 10 below.

FIG. 10 is a cross-sectional view of an electroluminescent display device according to a fifth exemplary embodiment of the present disclosure.

Since the fifth exemplary embodiment of the present disclosure shown in FIG. 10 differs from the electroluminescent display device according to the fourth exemplary embodiment of the present disclosure shown in FIG. 9, in that a step alleviation layer 590 is additionally disposed within a planarization layer 505 in the outer direction area of the trench 180, and other configurations thereof are substantially the same, a redundant description will be omitted. The same reference numerals are used for the same components.

Referring to FIG. 10, in the electroluminescent display device according to the fifth exemplary embodiment of the present disclosure, the buffer layer 102 and a driving element may be disposed on the substrate 101.

In addition, the planarization layer 505 may be disposed on the driving element.

In this case, in the fifth exemplary embodiment of the present disclosure, the step alleviation layer 590 is disposed in the planarization layer 505 of the non-active area NA.

The step alleviation layer 590 may be configured of a color filter constituting a color filter layer in the active area AA, and may include at least one of a red color filter, a green color filter, and a blue color filter.

The step alleviation layer 590 is disposed inside the planarization layer 505 in the outer direction area of the trench 180 and may serve to alleviate a step of the planarization layer 505 between the active area AA and the non-active area NA so as to maintain a constant pressure of a stamp when delamination of the cathode 153 is performed later. Accordingly, the delamination of the cathode 153 is smoothly performed, thereby improving process properties.

The planarization layer 505 may be disposed to cover the step alleviation layer 590.

A bank 506 may be formed in an area other than an emission area, on the planarization layer 505.

As in the fourth exemplary embodiment of the present disclosure described above, the trench 180 may be formed (patterned) to expose the planarization layer 505 in the bank 506 of the non-active area NA.

The bank 506 of the non-active area NA may be separated by the trench 180.

For example, the trench 180 may be formed in three surfaces of the non-active area NA except for the data pad portion, but is not limited thereto.

In addition, in the fourth exemplary embodiment of the present disclosure, the capping layer 120, the cathode 153, and the organic layer 152 on the trench 180 are removed by irradiating a laser, and the capping layer 120 and the cathode 153 on the second organic layer 152b in the outer direction area of the trench 180 may be removed (or delaminated) through a stamping method or the like. For example, when the trench 180 is formed in three surfaces of the non-active area NA except for the data pad portion, laser irradiation and the removal of the cathode 153 may also be performed on three surfaces of the non-active area NA except for the data pad portion.

In addition, in the fourth exemplary embodiment of the present disclosure, the inorganic layer 470 formed of an inorganic insulating material may be additionally disposed on the capping layer 120 including one side surface of the trench 180, but the present disclosure is not limited thereto.

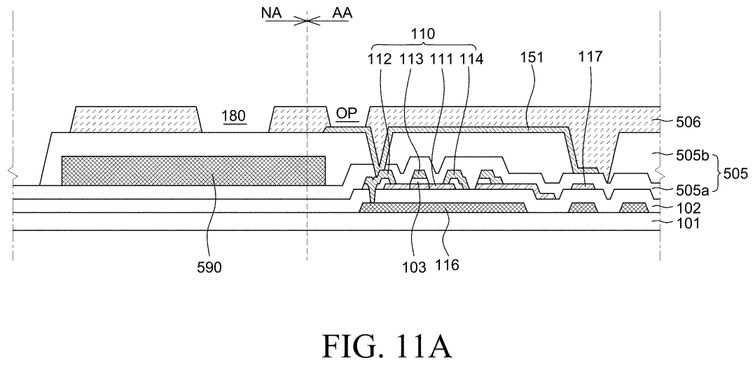

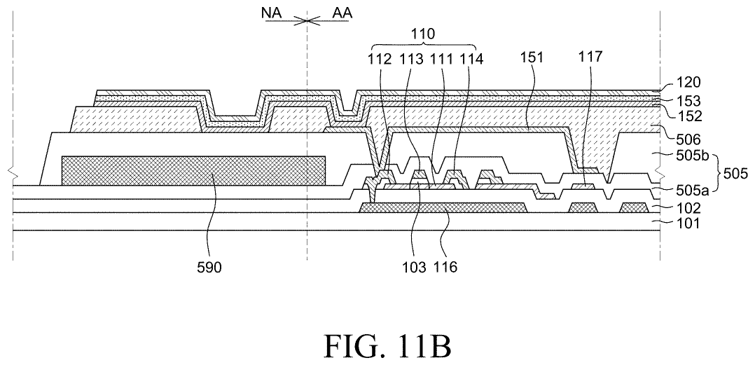

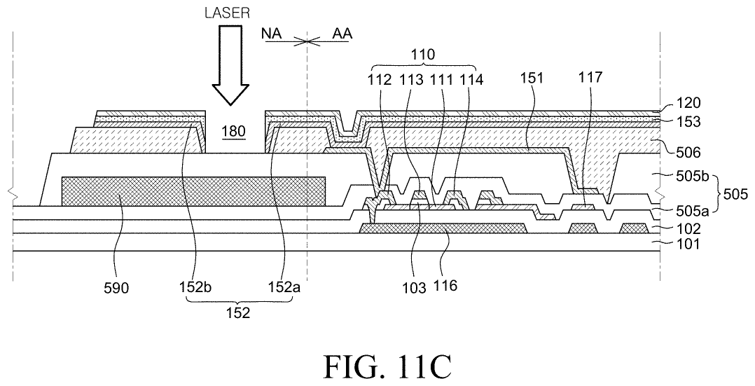

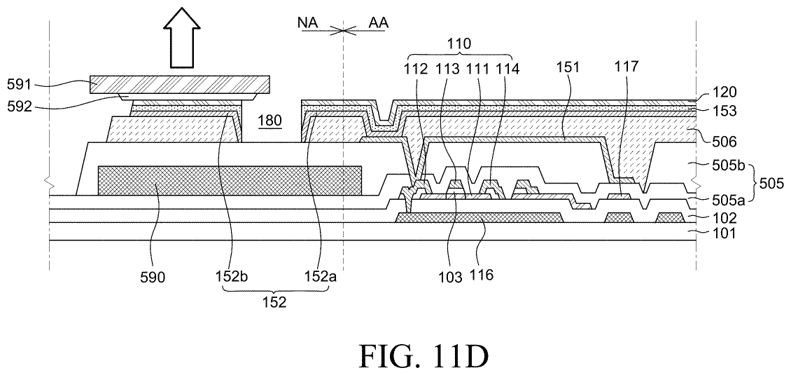

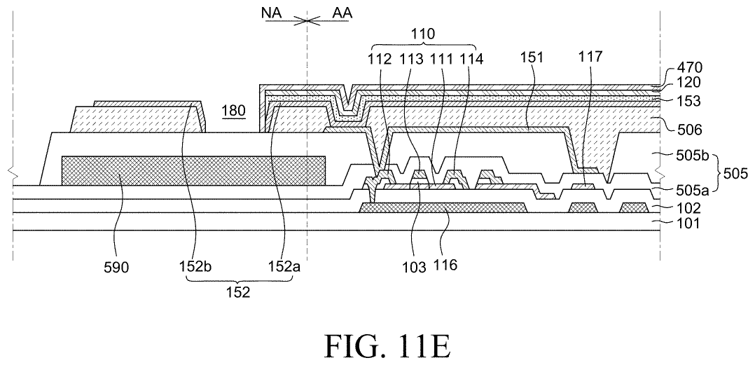

FIGS. 11A to 11E are cross-sectional views sequentially illustrating parts of a manufacturing process of the electroluminescent display device according to the fifth exemplary embodiment of the present disclosure of FIG. 10.

In FIGS. 11A to 11E, left sides show a manufacturing process of parts of the non-active area NA as an example, and right sides show a manufacturing process of parts of the active area AA as an example. In this case, for convenience of description, illustration is made with omission of a circuit unit of the non-active area NA. The circuit unit may include various components including a gate in panel (GIP) circuit.

Referring to FIG. 11A, various components of the pixel unit are formed on the substrate 101.

As described above, the pixel unit may be formed in the active area AA of the substrate 101 and may include various components under the organic layer.

That is, for example, the buffer layer 102 may be formed on the substrate 101.

The buffer layer 102 is a functional layer for protecting various electrodes and lines from impurities such as alkali ions leaking from the substrate 101 or underlying layers, and may have a multilayer structure including a first buffer layer and a second buffer layer, but the present disclosure is not limited thereto. The buffer layer 102 may be formed of silicon oxide (SiOx), silicon nitride (SiNx), or a multilayer thereof.

The light blocking layer 116 may be formed between the substrate 101 and the buffer layer 102.

The light blocking layer 116 may be formed at a position where the active layer 111 is to be formed on the substrate 101. The light blocking layer 116 may also be formed below a second storage electrode 117, but is not limited thereto. The light blocking layer 116 disposed below the second storage electrode 117 may be referred to as a first storage electrode.

The buffer layer 102 may be formed on the entire surface of the substrate 101 on which the light blocking layer 116 is formed. That is, the buffer layer 102 may be formed to extend to the non-active area NA.

The driving element 110 may be formed on the buffer layer 102.

The active layer 111 may be formed on the buffer layer 102. The active layer 111 may be formed of polysilicon (p-Si), and in this case, a predetermined region may be doped with impurities. In addition, the active layer 111 may be formed of amorphous silicon (a-Si) or various organic semiconductor materials such as pentacene. Furthermore, the active layer 111 may be formed of an oxide.

In addition, the second storage electrode 117 may be formed on the buffer layer 102, but is not limited thereto.

The interlayer insulating layer 103 may be formed on the active layer 111.

The interlayer insulating layer 103 may be formed of an insulating inorganic material such as silicon oxide (SiOx) or silicon nitride (SiNx), and besides, may also be formed of an insulating organic material.

The gate electrode 113 may be formed on the interlayer insulating layer 103. In addition, the source electrode 114 and the drain electrode 112 may be formed on the interlayer insulating layer 103. However, the present disclosure is not limited thereto, and after the gate electrode 113 is formed, the source electrode 114 and the drain electrode 112 may be formed on different layers.

The gate electrode 113, and the source electrode 114 and the drain electrode 112 may be formed in a single layer or multilayer structure, and may be formed of various conductive materials, for example, magnesium (Mg), aluminum (Al), nickel (Ni), chromium (Cr), molybdenum (Mo), tungsten (W), gold (Au) or an alloy thereof.

If necessary, a passivation layer formed of an inorganic insulating material may be additionally formed to cover the gate electrode 113, and the source electrode 114 and the drain electrode 112.

A first planarization layer 505a may be formed on the driving element 110 configured as described above.

The first planarization layer 505a may be formed to extend to the non-active area NA.

Meanwhile, in the case of the bottom emission method, a predetermined color filter layer may be formed on the first planarization layer 505a in the active area AA, but is not limited thereto.

In addition, the step alleviation layer 590 may be formed on the first planarization layer 505a in the non-active area NA, but is not limited thereto.

The step alleviation layer 590 may be formed of a color filter constituting a color filter layer in the active area AA, and may include at least one color filter among a red color filter, a green color filter, and a blue color filter.

Thereafter, a second planarization layer 505b may be formed on the first planarization layer 505a.

The second planarization layer 505b may include an overcoat layer, but is not limited thereto.

In the second planarization layer 505b of the active area AA, an upper region of the drain electrode 112 and an upper region of the second storage electrode 117 may be removed.

The second planarization layer 505b of the non-active area NA may be formed to be spaced apart from the end of the substrate 101 by a predetermined distance, but is not limited thereto.

Thereafter, the anode 151 may be formed on the second planarization layer 505b of the active area AA using a predetermined conductive material.

In this case, as described above, the electroluminescent display device may be implemented in a top emission method or bottom emission method. In the case of the top emission method, a reflective layer formed of an opaque conductive material with high reflectivity, for example, silver (Ag), aluminum (Al), gold (Au), molybdenum (Mo), tungsten (W), chromium (Cr) or an alloy thereof may be added under the anode 151.

On the other hand, in the case of the bottom emission method, the anode 151 may be formed of only a transparent conductive material such as indium tin oxide (ITO), indium zinc oxide (IZO), or indium gallium zinc oxide (IGZO).

Thereafter, the bank 506 may be formed on a remaining area other than the emission area and the trench 180 on the second planarization layer 505b by applying a predetermined insulating material. That is, the bank 506 of the active area AA may have an opening OP exposing a portion of the anode 151 corresponding to the emission area. Also, the bank 506 of the non-active area NA may have the trench 180 that exposes a portion of the planarization layer 505. The bank 506 of the non-active area NA may be separated by the trench 180.

For example, the trench 180 may be formed in three surfaces of the non-active area NA except for the data pad portion, but is not limited thereto.

The bank 106 may be formed of an inorganic insulating material such as silicon nitride (SiNx) or silicon oxide (SiOx), or an organic insulating material such as BCB, an acrylic resin, or an imide-based resin.

Thereafter, referring to FIG. 11B, the organic layer 152, the cathode 153, and the capping layer 120 may be sequentially formed on the substrate on which the bank 506 is formed.

The organic layer 152 may include an emission layer, an electron injection layer, an electron transport layer, a hole transport layer, a hole injection layer, and the like, but is not limited thereto.

The organic layer 152, the cathode 153, and the capping layer 120 may be formed to extend to the non-active area NA.

In the non-active area NA, the organic layer may be formed on the bank 106.

The capping layer 120 may be an organic layer formed of an organic material, and may be omitted if necessary.

Thereafter, referring to FIG. 11C, the organic layer 152, the cathode 153, and the capping layer 120 in the trench 180 may be removed by irradiating a LASER.

A UV laser of 355 nm may be used as the LASER.

For example, when the trench 180 is formed in three surfaces of the non-active area NA except for the data pad portion, laser irradiation may also be performed on the three surfaces of the non-active area NA except for the data pad portion. However, the present disclosure is not limited thereto.

In the non-active area NA, the organic layer 152 may be separated into portions by the trench 180 via laser irradiation. That is, the organic layer 152 may be separated into the first organic layer 152a in the inner direction area of the trench 180 and the second organic layer 152b in the outer direction area of the trench 180.

Thereafter, referring to FIGS. 11D and 11E, the capping layer 120 and cathode 153 that are unnecessary in the shadow area may be removed (or delaminated).

In this case, a stamping method using a weak adhesive force between the organic layer 152 and the cathode 153 may be applied.

For example, the capping layer 120 and cathode 153 that are unnecessary in the shadow area can be removed (or delaminated) by bringing a stamp 591 to which an adhesive or adhesive tape 592 is attached into contact with the capping layer 120 in the outer direction area of the trench 180 and applying pressure thereto.

Accordingly, the capping layer 120 and the cathode 153 on the second organic layer 152b in the outer direction area of the trench 180 may be delaminated and thus, the end of the cathode 153 may be retreated in the direction of the active area AA at the end of the first organic layer 152a in the inner direction area of the trench 180. Accordingly, the reliable bezel can be increased and the bezel width can be reduced.

Thereafter, the inorganic layer 470 may be additionally formed on the capping layer 120 including one side surface of the trench 180.

Thereafter, the adhesive layer and the encapsulation substrate may be sequentially formed on the substrate 101 on which the capping layer 120 is formed.

The exemplary embodiments of the present disclosure can also be described as follows:

According to an aspect of the present disclosure, there is provided an electroluminescent display device. The electroluminescent display device includes a display panel divided into an active area and a non-active area, a planarization layer extending to the non-active area of the display panel, a bank disposed on the planarization layer to extend to the non-active area and including a trench exposing the planarization layer of the non-active area; an organic layer disposed on the bank and separated by the trench, a cathode disposed on a first organic layer in the inner direction area of the trench and an adhesive layer and an encapsulation substrate disposed over the cathode, wherein the adhesive layer may be in contact with a second organic layer in the outer direction area of the trench.

The trench may be disposed in three surfaces of the non-active area except for a side of the display panel to which a flexible film may be connected.

The cathode may be not disposed on the second organic layer and in the trench.

The second organic layer may be spaced apart from an end of the bank by a predetermined distance in the non-active area.

The first organic layer may be disposed to extend over the bank in the inner direction area of the trench.

The first organic layer and the cathode may be disposed to extend over the bank in the inner direction area of the trench, wherein the electroluminescent display device may further include a capping layer disposed on the cathode that is disposed to extend over the bank in the inner direction area of the trench.

The capping layer together with the cathode may be spaced apart from an inner end of the second organic layer by a predetermined distance.

Ends of the first organic layer, the cathode, the capping layer, and the bank in the inner direction area of the trench may coincide with one another.

Inner ends of the bank in the outer direction area of the trench and the second organic layer may coincide with one another.

The trench may be formed of a plurality of lines of two or more lines.

The electroluminescent display device may further include an inorganic layer disposed on the capping layer including an inner side surface of the trench.

The inorganic layer may be formed of silicon oxide (SiOx), silicon nitride (SiNx), or a multilayer thereof.

The inorganic layer may be disposed on the second organic layer and on the capping layer, including an inner portion of the trench.

The electroluminescent display device may further include a step alleviation layer disposed in the planarization layer of the non-active area.

The step alleviation layer may include at least one color filter among a red color filter, a green color filter, and a blue color filter constituting a color filter layer in the active area.

The step alleviation layer may be disposed inside the planarization layer in the outer direction area of the trench.

The trench may further include an extension portion extending outwardly from the side of the display panel.

According to another aspect of the present disclosure, there is provided an electroluminescent display device. The electroluminescent display device includes a substrate divided into an active area and a non-active area, a planarization layer disposed on the substrate, a bank disposed on the planarization layer and including a trench formed in the non-active area to expose the planarization layer of the non-active area, a first organic layer and a second organic layer disposed on the bank and separated by the trench, a cathode and a capping layer disposed on the first organic layer and an adhesive layer and an encapsulation substrate disposed on the capping layer, wherein the cathode and the capping layer may be not disposed on the second organic layer and in the trench.

The electroluminescent display device may further include an inorganic layer disposed on the capping layer including an inner side surface of the trench.

The electroluminescent display device may further include a step alleviation layer disposed in the planarization layer of the non-active area, wherein the step alleviation layer may include at least one color filter among a red color filter, a green color filter, and a blue color filter constituting a color filter layer in the active area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An electroluminescent display device comprising:
a display panel including an active area and a non-active area;
a planarization layer extending to the non-active area of the display panel;
a bank on the planarization layer and extending to the non-active area, the bank including a trench that exposes a portion of the planarization layer in the non-active area;
an organic layer on the bank and separated by the trench, the organic layer including a first organic layer in an inner direction area of the trench and a second organic layer in an outer direction area of the trench;
a cathode on the first organic layer in the inner direction area of the trench; and
an adhesive layer and an encapsulation substrate over the cathode,
wherein the adhesive layer is in contact with the second organic layer that is in the outer direction area of the trench.

2. The electroluminescent display device of claim 1, wherein the trench is in three surfaces of the non-active area except for a side of the display panel to which a flexible film is connected.

3. The electroluminescent display device of claim 1, wherein the cathode is not on the second organic layer and in the trench.

4. The electroluminescent display device of claim 1, wherein the second organic layer is spaced apart from an end of the bank by a predetermined distance in the non-active area.

5. The electroluminescent display device of claim 1, wherein the first organic layer is extends over the bank in the inner direction area of the trench.

6. The electroluminescent display device of claim 1, wherein the first organic layer and the cathode extend over the bank in the inner direction area of the trench,
wherein the electroluminescent display device further includes a capping layer on the cathode that is disposed to extend over the bank in the inner direction area of the trench.

7. The electroluminescent display device of claim 6, wherein the capping layer and the cathode are spaced apart from an inner end of the second organic layer by a predetermined distance.

8. The electroluminescent display device of claim 6, wherein ends of the first organic layer, the cathode, the capping layer, and the bank in the inner direction area of the trench coincide with one another.

9. The electroluminescent display device of claim 8, wherein inner ends of the bank in the outer direction area of the trench and the second organic layer coincide with one another.

10. The electroluminescent display device of claim 1, wherein the trench comprises a plurality of lines.

11. The electroluminescent display device of claim 6, further comprising:
an inorganic layer on the capping layer, the inorganic layer including an inner side surface of the trench.

12. The electroluminescent display device of claim 11, wherein the inorganic layer comprises at least one of silicon oxide (SiOx), silicon nitride (SiNx), or a multilayer thereof.

13. The electroluminescent display device of claim 11, wherein the inorganic layer is on the second organic layer and on the capping layer, the inorganic layer including an inner portion of the trench.

14. The electroluminescent display device of claim 1, further comprising:
a step alleviation layer on the portion of the planarization layer in the non-active area.

15. The electroluminescent display device of claim 14, wherein the step alleviation layer includes at least one color filter among a red color filter, a green color filter, and a blue color filter constituting a color filter layer in the active area.

16. The electroluminescent display device of claim 14, wherein the step alleviation layer is inside the planarization layer in the outer direction area of the trench.

17. The electroluminescent display device of claim 2, wherein the trench further includes an extension portion extending outwardly from a side of the display panel.

18. An electroluminescent display device comprising:
a substrate including an active area and a non-active area;
a planarization layer on the substrate;
a bank on the planarization layer, the bank including a trench in the non-active area that exposes a portion of the planarization layer in the non-active area;
a first organic layer and a second organic layer on the bank and respectively separated by the trench;
a cathode and a capping layer disposed on the first organic layer; and
an adhesive layer and an encapsulation substrate disposed on the capping layer,
wherein the cathode and the capping layer are not on the second organic layer and in the trench.

19. The electroluminescent display device of claim 18, further comprising:
an inorganic layer on the capping layer, the inorganic layer including an inner side surface of the trench.

20. The electroluminescent display device of claim 18, further comprising:
a step alleviation layer on the portion of the planarization layer in the non-active area,
wherein the step alleviation layer includes at least one color filter among a red color filter, a green color filter, and a blue color filter constituting a color filter layer in the active area.
